(19) United States
(12) Patent Application Publication
(10) Pub. No.: US 2005/0285191 A1
(43) Pub. Date: Dec. 29, 2005

(54) Semiconductor device and method of fabricating the same

(75) Inventor: Kanna Tomiye, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/053,582

(22) Filed: Feb. 9, 2005

(30) Foreign Application Priority Data
Jun. 29, 2004 (JP) 2004-190847

(51) Int. Cl. H01L 29/76

(52) U.S. Cl. 257/344

(57) ABSTRACT

According to the present invention, there is provided a semiconductor device comprising: a gate electrode formed on a surface of a semiconductor device via a gate insulating film; gate electrode sidewalls formed on side surfaces of said gate electrode; a first source region and first drain region formed, in a surface portion of said semiconductor substrate, below said gate electrode sidewalls on two sides of a channel region positioned below said gate electrode; a second source region formed adjacent to a side, which is opposite to said channel region, of said first source region, and having a junction depth larger than that of said first source region, and a second rain region formed adjacent to a side, which is opposite to said channel region, of said first drain region, and having a junction depth larger than that of said first drain region; and a layer formed to a region deeper than said first source region and first drain region on the two sides of said channel region so as to sandwich said channel region, and containing a predetermined semiconductor material as an impurity.

### CROSS REFERENCE TO RELATED APPLICATION

This application is based upon and claims benefit of priority under 35 USC §119 from the Japanese Patent Application No. 2004-190847, filed on Jun. 29, 2004, the entire contents of which are incorporated herein by reference.

### BACKGROUND OF THE INVENTION

The present invention relates to a semiconductor device and a method of fabricating the same.

In recent MOS transistors, particularly, a p-channel MOS transistor (to be referred to as a pMOSFET hereinafter), the advance of micropatterning of devices poses the problem of a short channel effect (a phenomenon in which a leakage current flows between source and drain regions even when a gate electrode is closed, because the distance between the source and drain regions decreases as the gate length decreases), and the problem of an increase in parasitic resistance.

To solve the problem of the short channel effect and reduce the parasitic resistance, therefore, it is necessary in a pMOSFET to form a source extension region and drain extension region in which the junction depth (the distance from the surface to a junction) is small, and the impurity concentration distribution is steep.

One method of forming the source extension region and drain extension region as described above is to amorphize a semiconductor substrate by ion implantation of germanium or the like, and perform activation after ion implantation of boron or boron fluoride (BF₂).

If the activation is performed by the conventional annealing method which uses, e.g., a halogen lamp as a heating source, germanium is distributed shallower than boron in the direction of depth of the semiconductor substrate in order to reduce a leakage current that flows in junctions of the source and drain regions and the semiconductor substrate.

An example of the annealing method suited to forming a source extension region and drain extension region in which the junction depth is small and the impurity concentration distribution is steep is an activation technique which suppresses impurity diffusion by using flash lamp annealing or laser annealing.

In this activation technique which suppresses impurity diffusion, if germanium is formed shallower than boron, a region in which boron is distributed is not wholly amorphized. This decreases the activation ratio (the ratio of an activated portion) and extremely increases the parasitic resistance, thereby deteriorating the drivability of a pMOSFET. The following is a patent reference disclosing the prior art.
Japanese Patent Laid-Open No. 2002-329864

### SUMMARY OF THE INVENTION

According to one aspect of the present invention, there is provided a semiconductor device comprising:
a gate electrode formed on a surface of a semiconductor device via a gate insulating film;
gate electrode sidewalls formed on side surfaces of said gate electrode;
a first source region and first drain region formed, in a surface portion of said semiconductor substrate, below said gate electrode sidewalls on two sides of a channel region positioned below said gate electrode;
a second source region formed adjacent to a side, which is opposite to said channel region, of said first source region, and having a junction depth larger than that of said first source region, and a second rain region formed adjacent to a side, which is opposite to said channel region, of said first drain region, and having a junction depth larger than that of said first drain region; and

a layer formed to a region deeper than said first source region and first drain region on the two sides of said channel region so as to sandwich said channel region, and containing a predetermined semiconductor material as an impurity.

According to one aspect of the present invention, there is provided a semiconductor device fabrication method, comprising:
forming a gate electrode on a semiconductor substrate via a gate insulating film;
forming an amorphous layer by amorphization by implanting a predetermined semiconductor material into a surface portion of the semiconductor substrate by using the gate electrode as a mask;
forming a first source region and first drain region in a region shallower than the amorphous layer by ion-implanting a predetermined impurity into the surface portion of the semiconductor substrate by using the gate electrode as a mask;
forming gate electrode sidewalls on side surfaces of the gate electrode; and
forming a second source region and second drain region having a junction depth larger than that of the first source region and first drain region by ion-implanting a predetermined impurity into the surface portion of the semiconductor substrate by using the gate electrode and gate electrode sidewalls as masks.

According to one aspect of the present invention, there is provided a semiconductor device fabrication method, comprising:
forming a gate electrode on a semiconductor substrate via a gate insulating film;
forming a first source region and first drain region by ion-implanting a predetermined impurity into a surface portion of the semiconductor substrate by using the gate electrode as a mask;
forming an amorphous layer, which is amorphized to a region deeper than the first source region and first drain region, by amorphization by implanting a predetermined semiconductor material into the surface portion of the semiconductor substrate by using the gate electrode as a mask;
forming gate electrode sidewalls on side surfaces of the gate electrode; and
forming a second source region and second drain region having a junction depth larger than that of the first source region and first drain region by ion-implanting a predetermined impurity into the surface portion of the semiconductor substrate by using the gate electrode and gate electrode sidewalls as masks.

### BRIEF DESCRIPTION OF THE DRAWINGS

FIG. 1 is a sectional view showing the arrangement of a pMOSFET according to an embodiment of the present invention;

FIG. 2 is a sectional view showing, in an enlarged scale, a source extension region and its vicinity of the same pMOSFET;

FIG. 3 is a sectional view showing the arrangement of a pMOSFET as a comparative example in which germanium is formed shallower than boron;

FIG. 4 is a sectional view showing, in an enlarged scale, a source extension region and its vicinity of the same pMOSFET;

FIG. 5 is a sectional view showing a part of a fabrication process of fabricating the pMOSFET according to the embodiment of the present invention;

FIG. 6 is a sectional view showing a part of the fabrication process of fabricating the same pMOSFET;

FIG. 7 is a sectional view showing a part of the fabrication process of fabricating the same pMOSFET;

FIG. 8 is a sectional view showing a part of the fabrication process of fabricating the same pMOSFET;

FIG. 9 is a sectional view showing a part of the fabrication process of fabricating the same pMOSFET;

FIG. 10 is a sectional view showing a part of the fabrication process of fabricating the same pMOSFET;

FIG. 11 is a sectional view showing a part of the fabrication process of fabricating the same pMOSFET;

FIG. 12 is a sectional view showing a part of the fabrication process of fabricating the same pMOSFET;

FIG. 13 is a sectional view showing a part of the fabrication process of fabricating the same pMOSFET;

FIG. 14 is a sectional view showing a part of the fabrication process of fabricating the same pMOSFET;

FIG. 15 is a sectional view showing a part of the fabrication process of fabricating the same pMOSFET;

FIG. 16 is a sectional view showing a part of the fabrication process of fabricating the same pMOSFET;

FIG. 17 is a sectional view showing a part of the fabrication process of fabricating the same pMOSFET;

FIG. 18 is a graph showing the impurity distributions of germanium and boron in the substrate depth direction according to the embodiment of the present invention;

FIG. 19 is a graph showing the impurity distributions of germanium and boron in the substrate depth direction according to the comparative example in which germanium is formed shallower than boron;

FIG. 20 is a sectional view showing a part of a fabrication process of fabricating a pMOSFET according to another embodiment of the present invention; and

FIG. 21 is a sectional view showing a part of the fabrication process of fabricating the same pMOSFET.

### DETAILED DESCRIPTION OF THE EMBODIMENTS

Embodiments of the present invention will be described below with reference to the accompanying drawings.

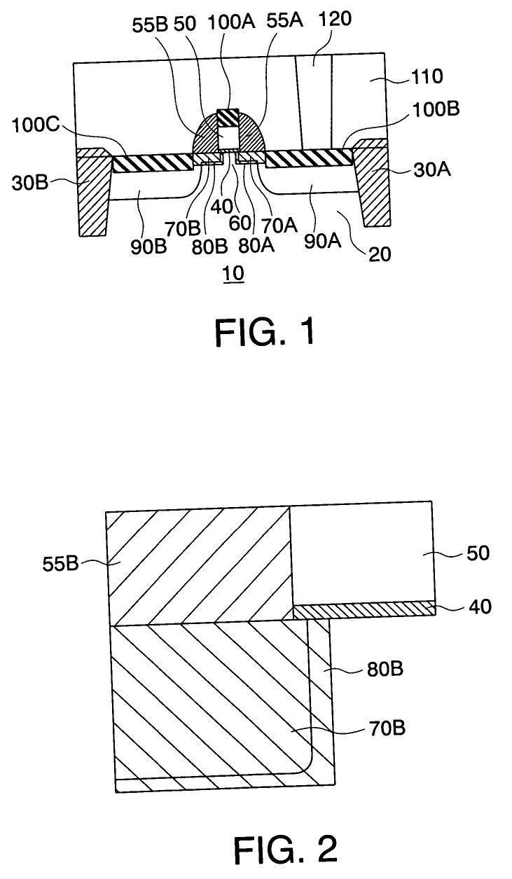

FIG. 1 shows the arrangement of a pMOSFET 10 of a semiconductor device according to an embodiment of the present invention. FIG. 2 shows details of the arrangement of a source extension region 70B and its vicinity of the pMOSFET 10. In the pMOSFET 10, element isolation insulating films 30A and 30B for element isolation are formed in the surface portion of a semiconductor substrate 20. In a central portion of an element region isolated by the element isolation insulating films 30A and 30B, a gate electrode 50 is formed via a gate insulating film 40 formed on the surface of the semiconductor substrate 20.

On the side surfaces of the gate electrode 50, gate electrode sidewalls 55A and 55B as insulating films are formed. Also, a channel region 60 in which an electric current flows is formed below the gate electrode 50 and near the surface of the semiconductor substrate 20.

At the two ends of the channel region 60, a source extension region 70B and drain extension region 70A in which the junction depth is small and the impurity concentration distribution is steep are formed. The junction depth is 30 [nm] or less (e.g., 10 [nm]) in order to meet micropatterning of devices. Note that the source extension region 70B corresponds to, e.g., a first source region, and the drain extension region 70A corresponds to, e.g., a first drain region.

In the pMOSFET 10, germanium layers 80B and 80A for amorphizing the semiconductor substrate 20 are distributed deeper in the semiconductor substrate 20 than boron for forming the source extension region 70B and drain extension region 70A. Note that the germanium layers 80B and 80A correspond to, e.g., layers containing a predetermined semiconductor material as an impurity.

A source region 90B having a junction depth of, e.g., 80 [nm] is formed between the source extension region 70B and element isolation insulating film 30B. Also, a drain region 90A having a junction depth of, e.g., 80 [nm] is formed between the drain extension region 70A and element isolation insulating film 30A. Note that the source region 90B corresponds to, e.g., a second source region, and the drain region 90A corresponds to, e.g., a second drain region.

In addition, silicide films 100A to 100C for reducing the parasitic resistance are formed on the surface of the gate electrode 50 and the surfaces of the source region 90B and drain region 90A. On the upper surfaces of the silicide films 100A to 100C, an interlayer dielectric film 110 is formed, and a contact plug 120 for wiring is also formed.

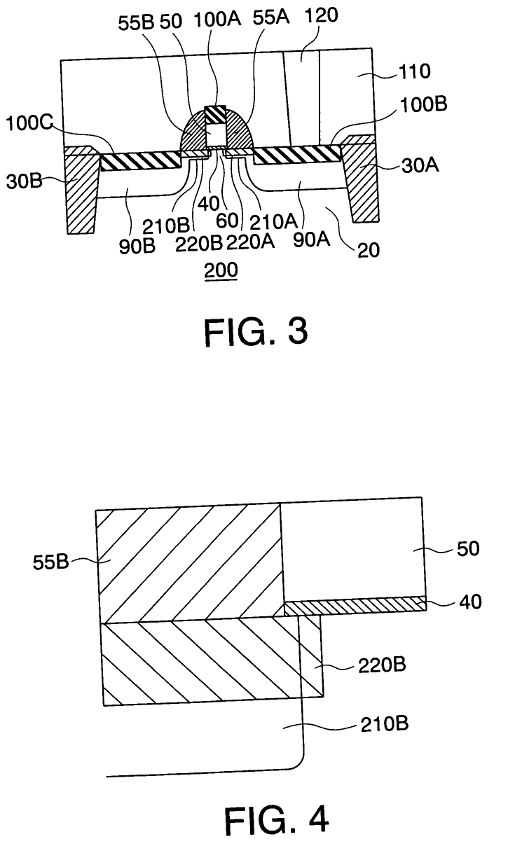

As a comparative example, FIG. 3 shows the arrangement of a pMOSFET 200 in which germanium layers 220B and 220A for amorphizing a semiconductor substrate 20 are distributed shallower than boron for forming a source extension region 210B and drain extension region 210A. FIG. 4 shows details of the arrangement of the source extension region 210B and its vicinity of the pMOSFET 200.

In the pMOSFET 200, the germanium layers 220B and 220A are formed shallower than boron. Therefore, a region in which boron is formed is not entirely amorphized, so the activation ratio decreases. As a consequence, the pMOSFET 200 poses the problem that the parasitic resistance increases and the drivability deteriorates.

By contrast, in the pMOSFET 10 according to this embodiment, the germanium layers 80B and 80A are formed deeper than boron. Accordingly, a region deeper than the region where boron is formed can be amorphized, and the activation ratio increases. In the pMOSFET 10, therefore, it is possible to reduce the parasitic resistance and improve the drivability.

Note that the same reference numerals as in FIGS. 1 and 2 denote the same elements, and a detailed explanation thereof will be omitted.

A method of fabricating the pMOSFET 10 according to this embodiment will be described below with reference to FIGS. 5 to 17. First, as shown in FIG. 5, element isolation insulating films 310A and 310B are formed on a semiconductor substrate 300, and ion implantation for forming a well region and channel region and annealing for activation are performed. As shown in FIG. 6, an insulating film 320 is formed on the surface of the semiconductor substrate 300.

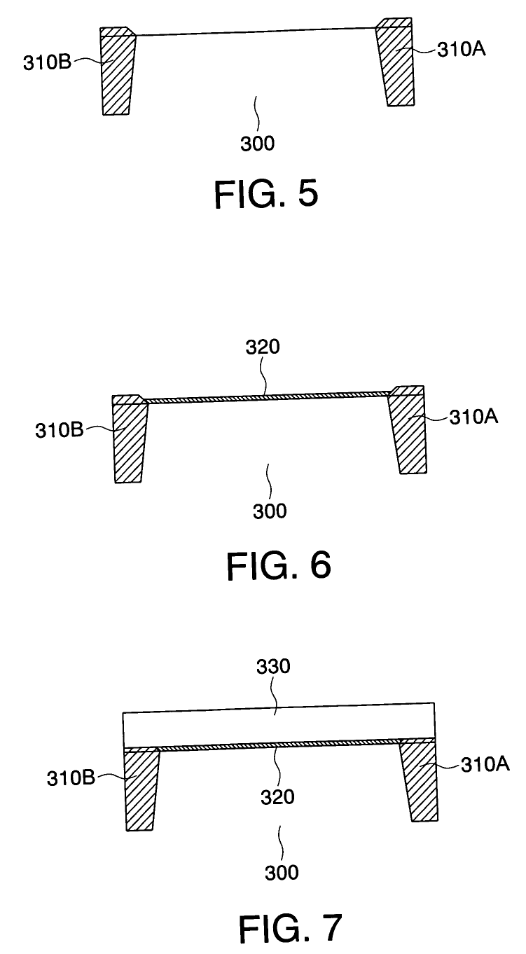

As shown in FIG. 7, a polysilicon film 330 is formed by depositing polysilicon on the insulating film 320 by CVD (Chemical Vapor Deposition). It is also possible to form a polysilicon germanium film by depositing polysilicon germanium on the insulating film 320.

As shown in FIG. 8, an impurity such as boron or boron fluoride (BF₂) is ion-implanted into the polysilicon film 330.

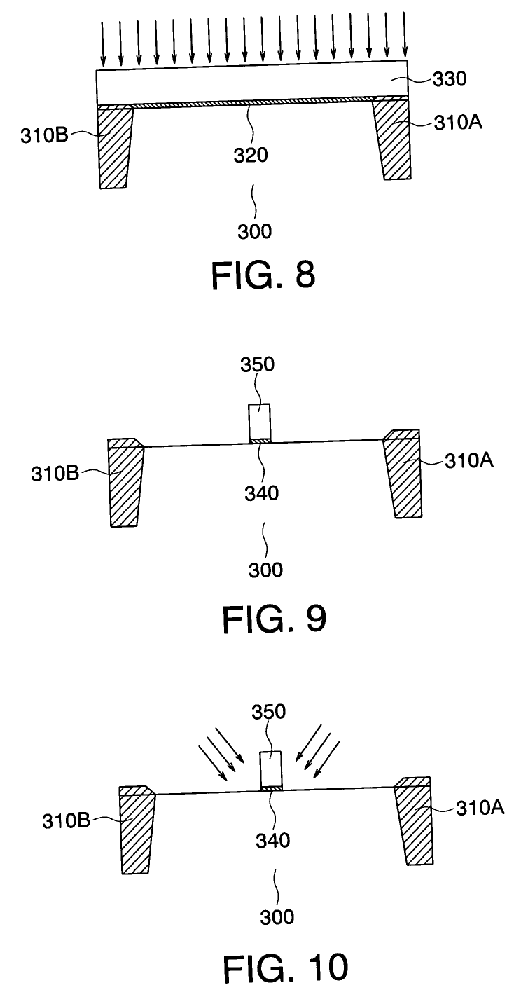

As shown in FIG. 9, a gate insulating film 340 and gate electrode 350 are formed by executing, e.g., a photoresist step and reactive ion etching (RIE) step.

As shown in FIG. 10, the gate electrode 350 is used as a mask to perform angle ion implantation of arsenic (As) or phosphorus (P) obliquely to the surface of the semiconductor substrate 300. After that, in order to activate the impurity implanted into the gate electrode 350, annealing for diffusing the impurity is performed.

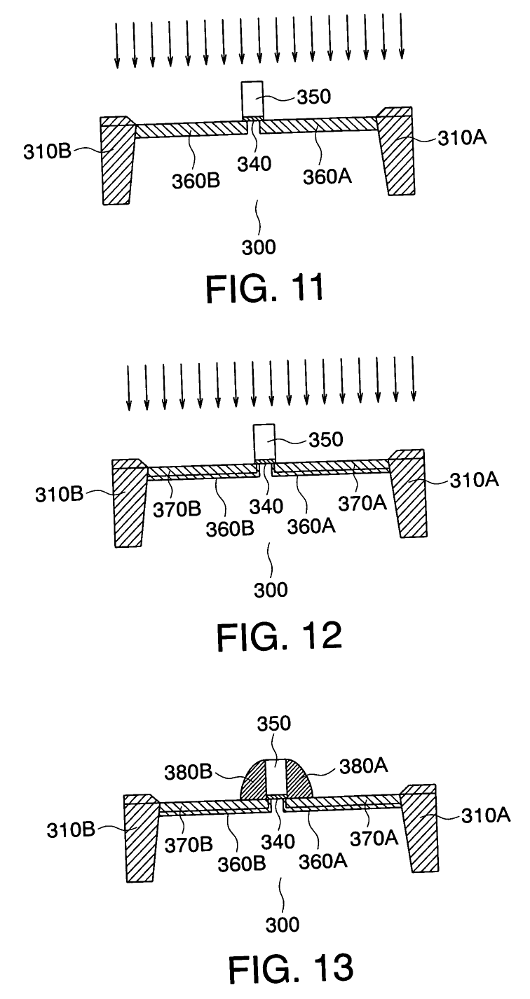

As shown in FIG. 11, ion implantation of the germanium is performed by selecting ion implantation conditions by which the surface portion of the semiconductor substrate 300 is well amorphized, thereby forming germanium layers 360B and 360A. It is also possible to form gallium layers by ion implantation of gallium.

As shown in FIG. 12, after ion implantation of boron or boron fluoride (BF₂) is performed, activation such as flash lamp annealing or laser annealing which suppresses diffusion of an impurity is performed to form a source extension region 370B and drain extension region 370A in which the junction depth is small and the impurity concentration distribution is steep. In this state, the germanium layers 360B and 360A crystallize. The ion implantation conditions of boron are, e.g., an acceleration energy of 1.0 keV or less, and a dose of 5×10¹⁵ to 2×10¹⁵/cm².

As shown in FIG. 13, an insulating film such as a silicon oxide film or silicon nitride film is formed on the entire surface of the semiconductor substrate 300 at a film formation temperature of, e.g., 600° C. or less. RIE is performed on this insulating film to form gate electrode sidewalls 380A and 380B on the side surfaces of the gate electrode 350.

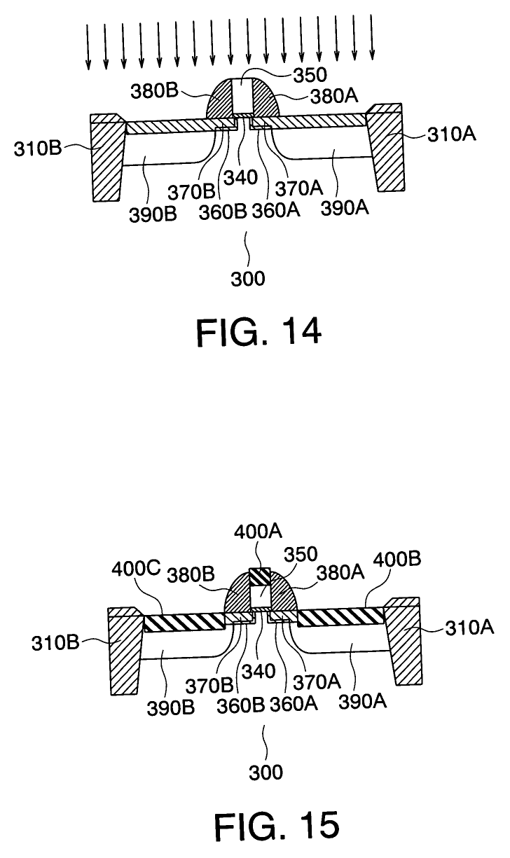

As shown in FIG. 14, the gate electrode 350 and gate electrode sidewalls 380A and 380B are used as masks to perform ion implantation of boron, and subsequently activation such as flash lamp annealing or laser annealing which suppresses diffusion of the impurity (boron) is performed, thereby forming a source region 390B and drain region 390A. The ion implantation conditions of boron are, e.g., an acceleration energy of 1.5 keV or more, and a dose of 1×10¹⁵ to 5×10¹⁵/cm².

As shown in FIG. 15, after a metal film of, e.g., nickel (Ni), cobalt (Co), or lead (Pb) is formed by sputtering, annealing is performed to form suicide films 400A to 400C for reducing the parasitic resistance on the surface of the gate electrode 350 and in the surface portions of the source region 390B and drain region 390A.

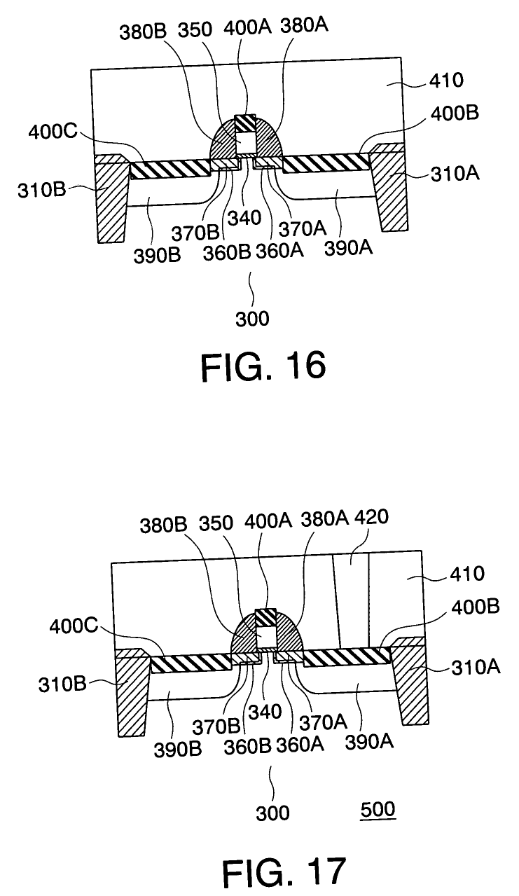

As shown in FIG. 16, an interlayer dielectric film 410 is formed, and the surface of the interlayer dielectric film 410 is planarized by CMP (Chemical Mechanical Polishing) or the like.

As shown in FIG. 17, a wiring step is performed by forming a contact plug 420 in the interlayer dielectric layer 410, thereby forming a pMOSFET 500.

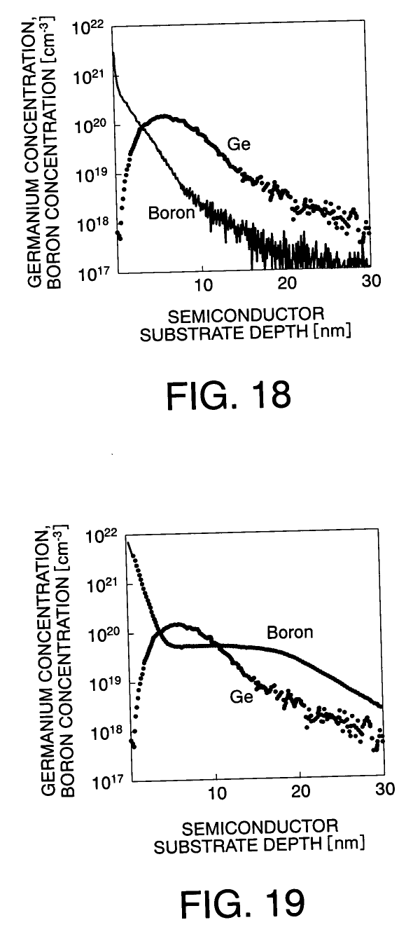

FIG. 18 shows an example of the relationship between the depth in the semiconductor substrate 20 and the germanium concentration and boron concentration in the pMOSFET 10 of this embodiment shown in FIGS. 1 and 2. Letting α be the depth at which the germanium concentration is, e.g., 10¹⁸ cm⁻³, and β (β is 30 [nm] or less) be the depth at which the boron concentration is the same concentration, 10¹⁸ cm⁻³. In the pMOSFET 10, α>β holds because the germanium layers 80B and 80A are present in a region deeper than boron in the source extension region 70B and drain extension region 70A.

By contrast, as shown in FIG. 19, in the pMOSFET 20 according to the comparative example shown in FIGS. 3 and 4, α<β holds because the germanium layers 220B and 220A are formed shallower than boron in the source extension region 210B and drain extension region 210A.

In this embodiment as described above, the germanium layers 80B and 80A are distributed deeper in the semiconductor substrate 20 than the impurity (boron) which forms the source extension region 70B and drain extension region 70A. Consequently, the semiconductor substrate 20 can be amorphized to a region deeper than the region in which the impurity is distributed.

Also, activation which suppresses diffusion of the impurity is performed in the source extension region 70B, drain extension region 70B, source region 90B, and drain region 90A. This increases the activation ratio (the ratio of an activated portion) in the amorphized region. As a consequence, the parasitic resistance in the source extension region 70B and drain extension region 70A can be reduced compared to the pMOSFET 200 shown in FIGS. 3 and 4 in which the amorphized region is small.

Accordingly, this embodiment can reduce the parasitic resistance of the pMOSFET 10 and improve the drivability of the pMOSFET 10.

In this embodiment, after ion implantation of germanium is performed as shown in FIG. 11, ion implantation of boron is performed as shown in FIG. 12. However, the present invention is not limited to this embodiment, and it is also possible to perform germanium ion implantation after boron ion implantation.

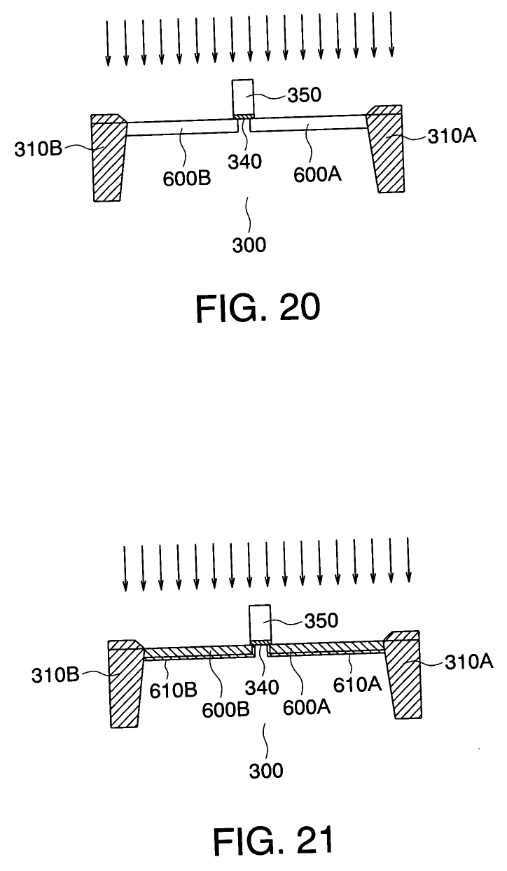

That is, as shown in FIG. 20, ion implantation of boron is performed to form a source extension region 600B and drain extension region 600A. Subsequently, as shown in FIG. 21, ion implantation of germanium is performed to form germanium layers 610B and 610A, thereby amorphizing a semiconductor substrate 300. After that, activation such as flash lamp annealing or laser annealing which suppresses diffusion of the impurity is performed. A pMOSFET is formed by executing steps similar to those shown in FIGS. 13 to 17 after that.

The above embodiment is merely an example, and hence does not limit the present invention. For example, the above-mentioned ion implantation conditions are examples, so various other ion implantation conditions can be applied.

1. A semiconductor device comprising:
a gate electrode formed on a surface of a semiconductor device via a gate insulating film;
gate electrode sidewalls formed on side surfaces of said gate electrode;
a first source region and first drain region formed, in a surface portion of said semiconductor substrate, below said gate electrode sidewalls on two sides of a channel region positioned below said gate electrode;
a second source region formed adjacent to a side, which is opposite to said channel region, of said first source region, and having a junction depth larger than that of said first source region, and a second rain region formed adjacent to a side, which is opposite to said channel region, of said first drain region, and having a junction depth larger than that of said first drain region; and
a layer formed to a region deeper than said first source region and first drain region on the two sides of said channel region so as to sandwich said channel region, and containing a predetermined semiconductor material as an impurity.

2. A device according to claim 1, wherein said first source region and first drain region have a junction depth of not more than 30 [nm].

3. A device according to claim 2, wherein said amorphous layer is formed by amorphization by implanting a predetermined semiconductor material into the surface portion of said semiconductor substrate by using said gate electrode as a mask.

4. A device according to claim 2, wherein said first source region and first drain region are formed by ion-implanting a predetermined impurity into the surface portion of said semiconductor substrate by using said gate electrode as a mask.

5. A device according to claim 2, wherein said second source region and second drain region are formed by ion-implanting a predetermined impurity into the surface portion of said semiconductor substrate by using said gate electrode and gate electrode sidewalls as masks.

6. A device according to claim 1, wherein the semiconductor device comprises a pMOSFET.

7. A device according to claim 1, wherein said amorphous layer is formed by amorphization by implanting a predetermined semiconductor material into the surface portion of said semiconductor substrate by using said gate electrode as a mask.

8. A device according to claim 1, wherein said first source region and first drain region are formed by ion-implanting a predetermined impurity into the surface portion of said semiconductor substrate by using said gate electrode as a mask.

9. A device according to claim 1, wherein said second source region and second drain region are formed by ion-implanting a predetermined impurity into the surface portion of said semiconductor substrate by using said gate electrode and gate electrode sidewalls as masks.

10. A device according to claim 1, wherein said first source region and first drain region and said second source region and second drain region are formed by activation which suppresses diffusion of an impurity.

11. A semiconductor device fabrication method, comprising;
forming a gate electrode on a semiconductor substrate via a gate insulating film;
forming an amorphous layer by amorphization by implanting a predetermined semiconductor material into a surface portion of the semiconductor substrate by using the gate electrode as a mask;
forming a first source region and first drain region in a region shallower than the amorphous layer by ion-implanting a predetermined impurity into the surface portion of the semiconductor substrate by using the gate electrode as a mask;
forming gate electrode sidewalls on side surfaces of the gate electrode; and
forming a second source region and second drain region having a junction depth larger than that of the first source region and first drain region by ion-implanting a predetermined impurity into the surface portion of the semiconductor substrate by using the gate electrode and gate electrode sidewalls as masks.

12. A method according to claim 11, wherein the first source region and first drain region have a junction depth of not more than 30 [nm].

13. A method according to claim 12, wherein the first source region and first drain region and the second source region and second drain region are formed by activation which suppresses diffusion of an impurity.

14. A method according to claim 11, wherein the semiconductor device comprises a pMOSFET.

15. A device according to claim 11, wherein said first source region and first drain region and said second source region and second drain region are formed by activation which suppresses diffusion of an impurity.

16. A semiconductor device fabrication method, comprising;
forming a gate electrode on a semiconductor substrate via a gate insulating film;
forming a first source region and first drain region by ion-implanting a predetermined impurity into a surface portion of the semiconductor substrate by using the gate electrode as a mask;
forming an amorphous layer, which is amorphized to a region deeper than the first source region and first drain region, by amorphization by implanting a predetermined semiconductor material into the surface portion of the semiconductor substrate by using the gate electrode as a mask;
forming gate electrode sidewalls on side surfaces of the gate electrode; and
forming a second source region and second drain region having a junction depth larger than that of the first source region and first drain region by ion-implanting a predetermined impurity into the surface portion of the semiconductor substrate by using the gate electrode and gate electrode sidewalls as masks.

17. A method according to claim 16, wherein the first source region and first drain region have a junction depth of not more than 30 [nm].

18. A method according to claim 17, wherein when the first source region and first drain region are formed, and when the second source region and second drain region are formed, the first source region and first drain region and the second source region and second drain region are formed by activation which suppresses diffusion of an impurity, after ion implantation is performed.

19. A method according to claim 16, wherein the semiconductor device comprises a pMOSFET.

20. A method according to claim 16, wherein when the first source region and first drain region are formed, and when the second source region and second drain region are formed, the first source region and first drain region and the second source region and second drain region are formed by activation which suppresses diffusion of an impurity, after ion implantation is performed.
